(19) United States
(12) Patent Application Publication
(10) Pub. No.: US 2008/0020293 A1
(43) Pub. Date: Jan. 24, 2008

(54) Vortex mask and method for preparing the same and method for preparing a circular pattern using the same

(75) Inventor: Yee Kai Lai, Jungli City (TW)

Correspondence Address: OLIFF & BERRIDGE, PLC, P.O. BOX 320850, ALEXANDRIA, VA, 22320-4850, US

(73) Assignee: PROMOS TECHNOLOGIES INC., HSINCHU (TW)

(21) Appl. No.: 11/529,496

(22) Filed: Sep. 29, 2006

(30) Foreign Application Priority Data
Jul. 21, 2006 (TW) 095126641

(51) Int. Cl. G03C 5/00; G03F 1/00

(52) U.S. Cl. 430/5; 430/394; 430/322; 430/324

(57) ABSTRACT

A vortex mask comprises a substrate, a first phase region positioned on the substrate, a second phase region surrounding the first phase region, and a third phase region positioned on the substrate and connected to the first phase region and the second phase region. When exposure beams penetrate the first phase region, the second phase region and the third region of the vortex mask, there will be 90 degrees of phase difference from each other. In addition, the first phase region and the third phase region can be positioned in a mirror image manner, and the third phase region connects to the first phase region and the second phase region in a point manner, which can be used to define the shape of a circular pattern.

### BACKGROUND OF THE INVENTION

1. Field of the Invention

The present invention relates to a vortex mask and method for preparing the same and method for preparing a circular pattern using the same, and more particularly, to a vortex mask capable of preventing an exposing light from forming a destructive interference and method for preparing the same and method for preparing a circular pattern using the same.

2. Description of the Related Art

FIG. 1 shows a vortex mask 10 according to the prior art, disclosed in U.S. Pat. No. 6,811,933. The vortex mask 10 comprises a substrate 12 and four connected rectangular phase regions 14, 16, 18 and 20. An exposing light (not shown in the drawing) will have different phases of 0°, 90°, 180°, and 270° after penetrating through the vortex mask 10. There are 90 degrees (90°) of phase difference between the four rectangular phase regions 14, 16, 18 and 20, and the intersection of the four rectangular phase regions 14, 16, 18 and 20 is a singular point, which can be used to define the shape of a circular pattern 26.

FIG. 2 shows the application of the vortex mask 10 to define the shape of the circular pattern 26. The thickness of the substrate 12 in the four rectangular phase regions 14, 16, 18 and 20 is designed to be different such that there are 90 degrees (90°) of phase difference between the four phase regions 14, 16, 18 and 20 as an exposing light 34 penetrates the different phase regions with different thicknesses of substrate 12.

FIG. 3 shows a simulated optical intensity distribution of the vortex mask 10 using an optical simulation software called SOLID-E. The optical intensity distribution of the vortex mask 10 includes a dark region 22 at the intersection of the four rectangular phase regions 14, 16, 18 and 20, i.e., at a singular point. If a photoresist layer 32 on a semiconductor substrate 30 is made of negative photoresist material, a circular pattern 26 can be formed in the photoresist layer 32 corresponding to the circular dark region 22 by performing an exposing process using the vortex mask 10 and a developing process after the exposing process.

However, the phase difference between the rectangular phase region 18 (having a phase 180°) and the adjacent substrate 12 (having a phase 0°) is 180°, the exposing light 34 penetrating through the vortex mask forms a L-shaped dark region 24 due to the destructive interference, and the L-shaped dark region 24 further forms a corresponding L-shaped opening in the photoresist layer 32 after the developing process. To avoid the formation of the unwanted L-shaped opening in the photoresist layer 32, the prior art uses another mask having a corresponding L-shaped bright region to perform a second exposing process in addition to the first exposing process using the vortex mask 10 before performing the developing process. In other words, the prior art needs to perform the exposing process twice by using the vortex mask 10 to define the shape of the circular pattern 26 in the photoresist layer 32, which raises the alignment issue and decreases the throughput of the lithographic process.

### SUMMARY OF THE INVENTION

One aspect of the present invention provides a vortex mask capable of preventing an exposing light from forming the destructive interference and method for preparing the same and method for preparing a circular pattern using the same, which needs only one exposing process without raising the alignment issue of the two exposing process and can increase the throughput of the lithographic process.

A vortex mask according to this aspect of the present invention comprises a substrate, a first phase region positioned on the substrate, a second phase region surrounding the first phase region and a third phase region positioned on the substrate and connecting to the first phase region and the second phase region. There are 90 degrees of phase difference as an exposing light penetrates through the first phase region, the second phase region and the third phase region. The first phase region can be triangular, the second phase region includes a triangular portion and a concave-shaped portion, and the first phase region and the triangular portion of the second phase region form a rectangular region, which is positioned in a concave of the concave-shaped portion. Preferably, the first phase region and the third phase region are positioned in a mirror image manner.

Another aspect of the present invention provides a method for preparing a vortex mask comprising the steps of forming a first phase region with a predetermined thickness including (a) forming a polymer layer having the predetermined thickness on a substrate, (b) changing the molecular structure of the polymer layer in a predetermined region and (c) removing a portion of the polymer layer outside the predetermined region, and repeating the steps (a), (b) and (c) twice to form a second phase region and a third phase region with different thickness. Preferably, the third phase region forms a point connection with the first phase region and the second phase region.

Another aspect of the present invention provides a method for preparing a circular pattern by a step of forming a photoresist layer on a substrate and a step of exposing the photoresist layer by using a vortex mask. The vortex mask includes a substrate, a first phase region positioned on the substrate, a second phase region surrounding the first phase region and a third phase region positioned on the substrate and connecting to the first phase region and the second phase region. The method then performs a step of developing the photoresist layer to form the circular pattern positioned at a connecting site of the first phase region, the second phase region and the third phase region.

The prior art vortex mask possesses the L-shaped dark region due to the destructive interference, which necessitate a second exposing process using another mask having a corresponding L-shaped bright region in addition to the first exposing process using the vortex mask. The requirement of performing the exposing process twice raises the alignment issue and reduces the throughput of the lithographic process. In contrast, the intensity distribution of the present vortex mask possesses the circular dark region and no L-shaped dark region, and therefore the present invention does not need to perform a corresponding second exposing process. Consequently, the present invention does not have alignment issues and can increase the throughput of the lithographic process.

### BRIEF DESCRIPTION OF THE DRAWINGS

The objectives and advantages of the present invention will become apparent upon reading the following description and upon reference to the accompanying drawings in which:

FIG. 1 shows a vortex mask according to the prior art;

FIG. 2 shows the application of the vortex mask to define the shape of the circular pattern according to the prior art;

FIG. 3 shows a simulated optical intensity distribution of the vortex mask using an optical simulation software called SOLID-E;

FIG. 4 illustrates a vortex mask according to one embodiment of the present invention;

FIG. 5 to FIG. 8 illustrate a method for preparing the vortex mask according to one embodiment of the present invention;

FIG. 9 is a schematic diagram showing the application of the vortex mask to define the shape of the circular pattern on a semiconductor substrate according to one embodiment of the present invention; and

FIG. 10 shows simulated optical intensity distribution of the vortex mask using SOLID-E.

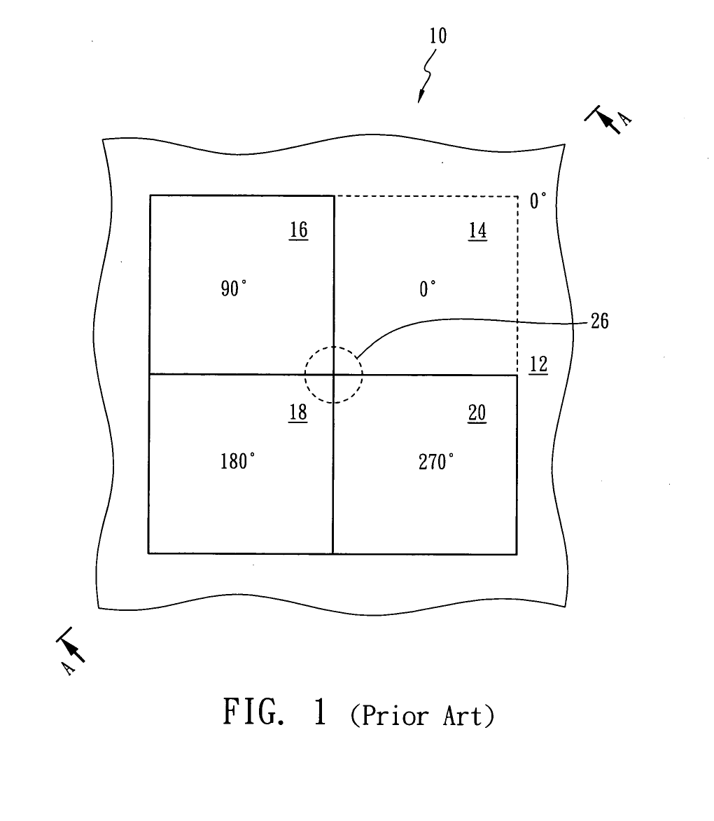

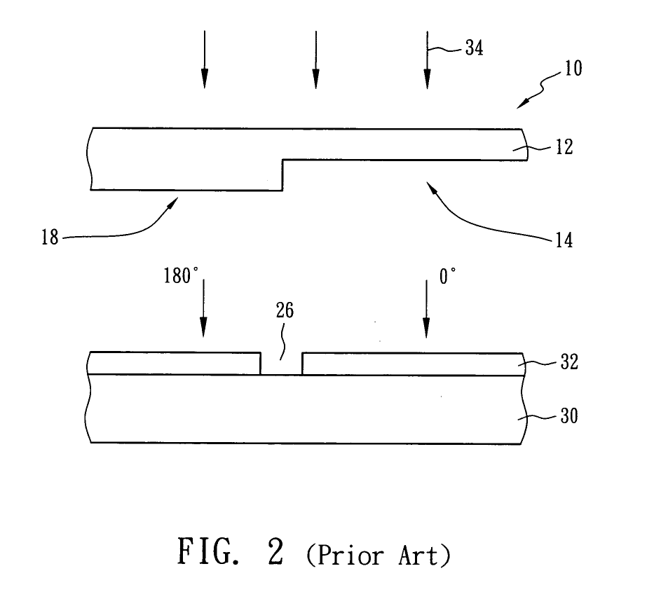

### DETAILED DESCRIPTION OF THE INVENTION

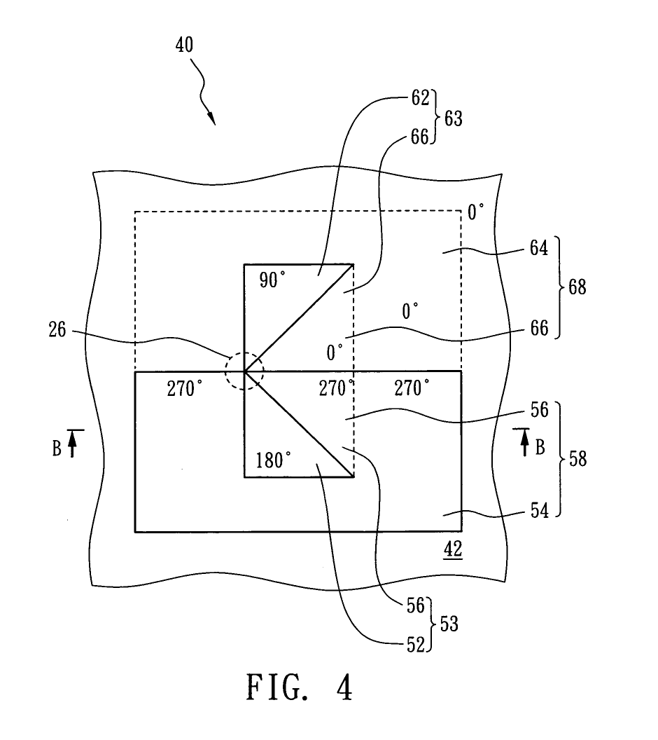

FIG. 4 illustrates a vortex mask 40 according to one embodiment of the present invention. The vortex mask 40 comprises a substrate 42, a first phase region 52 positioned on the substrate 42, a second phase region 58 surrounding the first phase region 52, a third phase region 62 positioned on the substrate 42 and a fourth phase region 68 surrounding the third phase region 62. The third phase region 62 connects to the first phase region 52 and the second phase region 58, and the intersection is a singular point, which can be used to define the shape of a circular pattern 26. Preferably, the first phase region 52 and the third phase region 62 are positioned in a mirror image manner, and the second phase region 58 and the fourth phase region 68 are positioned in a mirror image manner.

In addition, the third phase region 62 forms a point connection with the first phase region 52 and the second phase region 58. The first phase region 52 can be triangular, the second phase region 58 includes a triangular portion 56 and a concave-shaped portion 54, and the first phase region 52 and the triangular portion 56 of the second phase region 58 form a rectangular region 53, which is positioned in a rectangular concave of the concave-shaped portion 54. Similarly, the third phase region 62 can be triangular, the fourth phase region 68 includes a triangular portion 66 and a concave-shaped portion 64, and the third phase region 62 and the triangular portion 66 of the fourth phase region 68 form a rectangular region 63, which is positioned in a rectangular concave of the concave-shaped portion 64. As an exposing light penetrates the first phase region 52, the second phase region 58, the third phase region 62, and the fourth phase region 68, there are 90 degrees of phase difference. Therefore, the first phase region 52 can be considered as a 180° region, the second phase region 58 can be considered as a 270° region, the third phase region 62 can be considered as a 90° region, and the fourth phase region 68 can be considered as a 0° region.

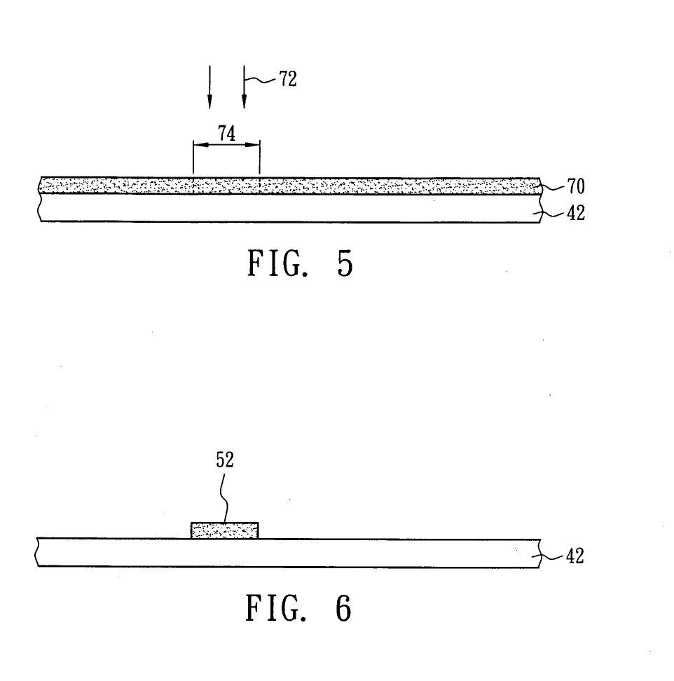

FIG. 5 to FIG. 8 illustrate a method for preparing the vortex mask 40 according to one embodiment of the present invention, wherein FIG. 5 to FIG. 8 are cross-sectional diagrams along a cross-sectional line B-B in FIG. 4. The method includes the step of (a) performing a spin-coating process to form a polymer layer 70 having a predetermined thickness on the substrate 42, (b) providing energy to a predetermined region 74 such as irradiating electron beam 72 to the predetermined region 74 in the polymer layer 70 to change the molecular structure of the polymer layer 70 in a predetermined region 74, and (c) performing a developing process to remove a portion of the polymer layer 70 outside the predetermined region 74 to form the first phase region 52 with the predetermined thickness, as shown in FIG. 6.

The polymer layer 70 may be made of material including silsesquioxane. For example, the silsesquioxane can be hydrogen silsesquioxane (HSQ), and the developing process may use alkaline solution to remove the polymer layer 70 not irradiated by the electron beam 72, wherein the alkaline solution is selected from the group consisting of sodium hydroxide (NaOH) solution, potassium hydroxide (KOH) solution, and tetramethylamomnium hydroxide (TMAH) solution. In addition, the silsesquioxane can be methylsilsesquioxane (MSQ), and the developing process may use an alcohol solution such as an ethanol solution to remove the polymer layer 70 not irradiated by the electron beam 72. Further, the polymer layer 70 can be made of material including hybrid organic siloxane polymer (HOSP), and the developing process may use a propyl acetate solution to remove the polymer layer 70 not irradiated by the electron beam 72.

The irradiation of the electron beam 72 will change the molecular structure of the polymer layer 70, for example, the molecular structure of hydrogen silsesquioxane will transform into a network structure from a cage-like structure and chemical bonds will be formed between the polymer layer 70 and the quartz substrate 52. As a result, it is possible to selectively remove the polymer layer 70 outside the predetermined region 74 by the developing process using alkaline solution.

According to the known phase shifting formula: P=2π(n−1)d/mλ, where, P represents phase shifting angle, n represents the reflection index, d represents the thickness of the phase shifting pattern, m represents an odd number, and λ represents the wavelength of the exposure beam. When the wavelength of the exposure light is set to be 193 nanometer, the corresponding reflection index of the polymer layer 70 is about 1.52, and the thickness of the first phase region 52 calculated according to the phase shifting formula should be 1828 Å. If the tolerance of the phase shifting angle is set to be 177° to 183°, the thickness of the first phase region 52 should be 1797 to 1858 Å.

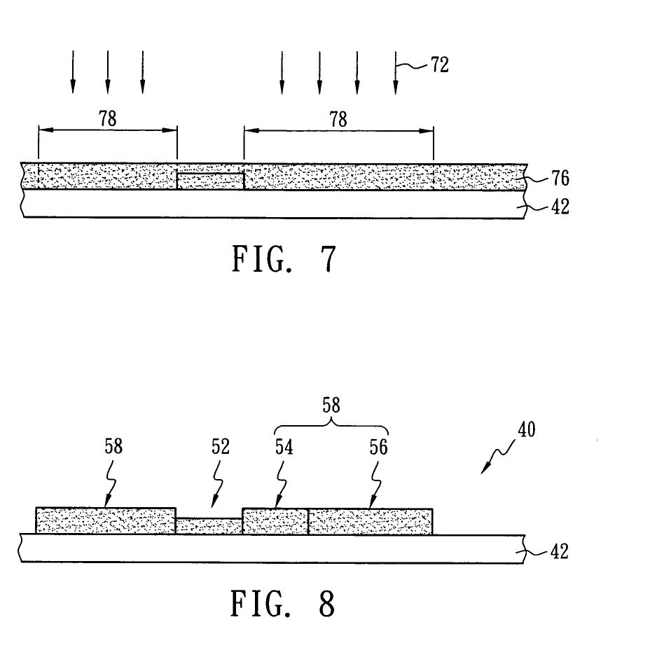

Referring to FIG. 7 and FIG. 8, the aforementioned steps (a), (b) and (c) are repeated for predetermined times (twice) to form the second phase region 58 and the third phase region 62 with different thicknesses of polymer material on the substrate 42 to complete the vortex mask 40. For example, a polymer layer 76 is formed by spin-coating process on the substrate 42, the electron beam 72 then irradiates on a portion of the polymer layer 76, and a developing process is performed to form the second phase region 58, as shown in FIG. 7 and FIG. 8. The third phase region 62 can be prepared by repeating steps (a), (b) and (c) again. Compared to the first phase region 52, the second phase region 58 and the third phase region 62 possess different thicknesses of polymer material, and there is no polymer material on the substrate 42 in the fourth phase region 68.

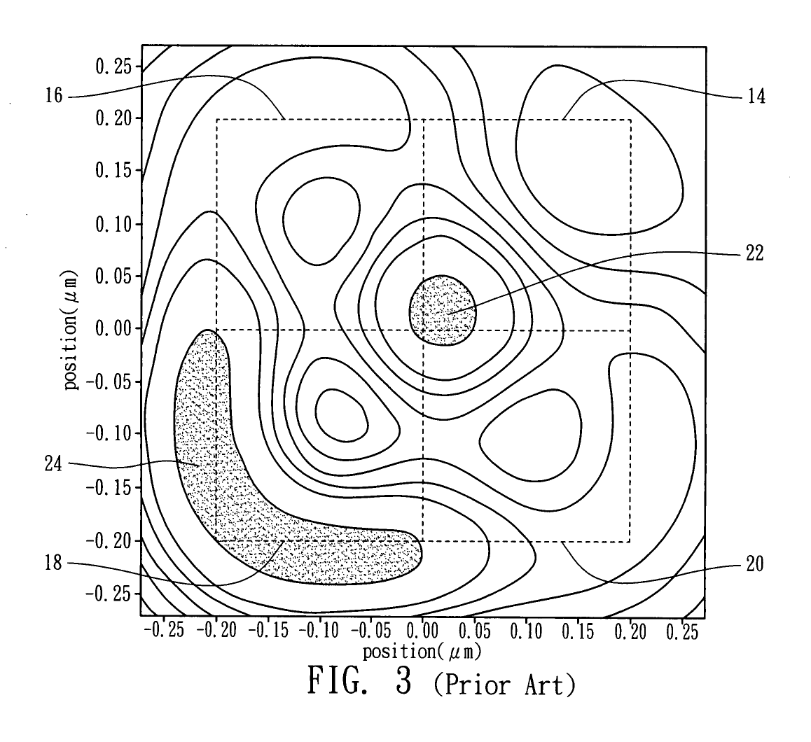

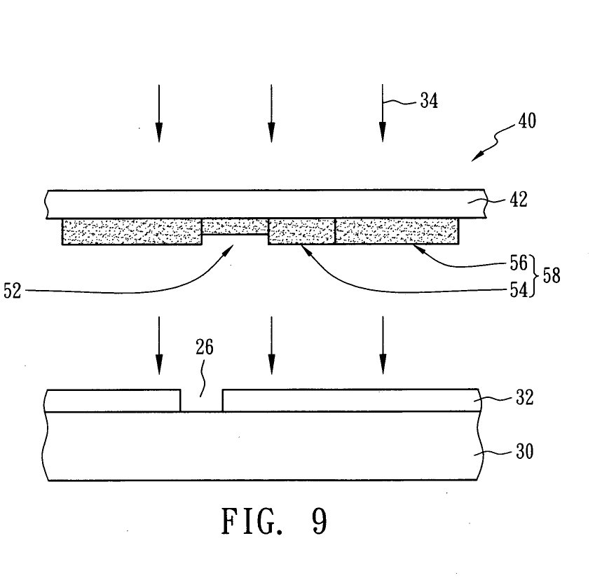

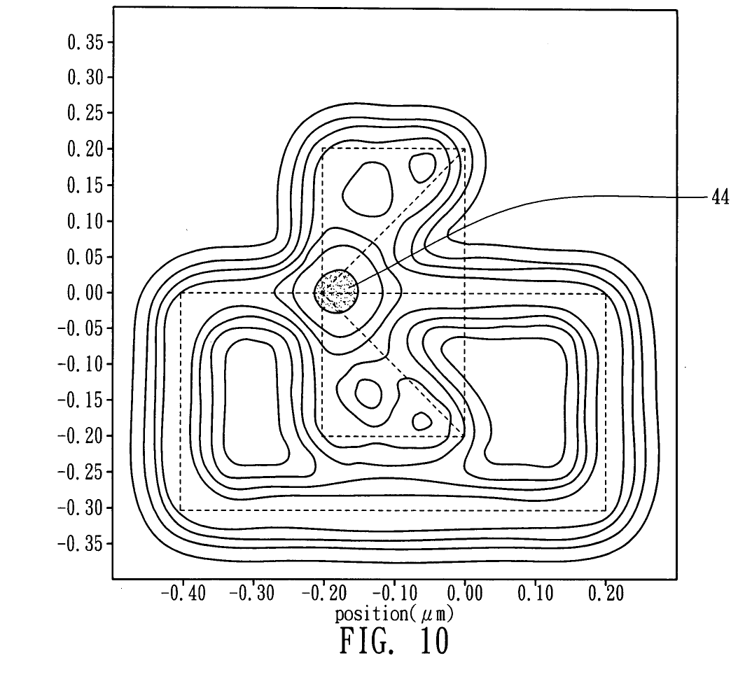

FIG. 9 is a schematic diagram showing the application of the vortex mask 40 to define the shape of the circular pattern 26 on a semiconductor substrate 30 according to one embodiment of the present invention, wherein the phase shifting mask 50 is a cross-sectional view along a cross-sectional line B-B in FIG. 3. The surface of the semiconductor substrate 30 is coated with a photoresist layer 32, which is preferably made of negative photoresist material. To define the shape of the circular pattern 26 in the photoresist layer 32, the present invention uses an exposing light 34 and the vortex mask 40 to expose the photoresist layer 32, and a developing process is then performed to remove a portion of the photoresist layer 32 not irradiated by the exposing light 34.

FIG. 10 shows simulated optical intensity distribution of the vortex mask 40 using SOLID-E. The optical intensity distribution of the vortex mask 40 shows a circular dark region 44 at the intersection of the first phase region 52, the second phase region 58, the third phase region 62 and the fourth phase region 68. If the photoresist layer 32 is made of negative photoresist material, the circular pattern 26 can be formed in the photoresist layer 32 corresponding to the connection site by performing an exposing process using the vortex mask 40 and a developing process.

As the exposing light 34 penetrate any two adjacent phase regions of the vortex mask 40, the phase difference is not 1800, i.e., the destructive interference does not occur, and the optical intensity distribution of the vortex mask 40 does not have the L-shaped dark region 24 of the conventional vortex mask 10. In particular, the optical intensity distribution of the vortex mask 40 has only the circular dark region 44 to define the shape of the circular pattern 26, and it is not necessary to perform a second expose process using another mask having an L-shape bright region. In other words, to define the shape of the circular pattern 26, the present invention needs to perform the exposing process only once using the vortex mask 40.

The prior art vortex mask 10 possesses the L-shaped dark region 24 due to destructive interference, which necessitates a second exposing process using another mask having a corresponding L-shaped bright region in addition to the first exposing process using the vortex mask 10. The requirement of performing the exposing process twice raises the alignment issue and reduces the throughput of the lithographic process. In contrast, the optical intensity distribution of the present vortex mask 40 possesses the circular dark region 44 and no L-shaped dark region, and therefore the present invention does not need to perform a corresponding second exposing process. Consequently, the present invention does not have alignment issues and can increase the throughput of the lithographic process.

The above-described embodiments of the present invention are intended to be illustrative only. Numerous alternative embodiments may be devised by those skilled in the art without departing from the scope of the following claims.

What is claimed is:

1. A vortex mask, comprising:
a substrate;
a first phase region positioned on the substrate;
a second phase region surrounding the first phase region; and
a third phase region positioned on the substrate and connecting to the first phase region and the second phase region.

2. The vortex mask of claim 1, wherein the first phase region and the second phase region are configured to generate 90 degrees of phase difference for a penetrating exposing light.

3. The vortex mask of claim 1, wherein the first phase region and the third phase region are configured to generate 90 degrees of phase difference for a penetrating exposing light.

4. The vortex mask of claim 1, wherein the third phase region forms a point connection with the first phase region and the second phase region, and the second phase region and the third phase region are configured to generate 90 degrees of phase difference for a penetrating exposing light.

5. The vortex mask of claim 1, wherein the first phase region is triangular, and the second phase region includes a triangular portion and a concave-shaped portion.

6. The vortex mask of claim 5, wherein the first phase region and the triangular portion of the second phase region form a rectangular region, and the rectangular region is positioned in a rectangular concave of the concave-shaped portion.

7. The vortex mask of claim 1, further comprising a fourth phase region surrounding the third phase region.

8. The vortex mask of claim 7, wherein the third phase region is triangular, and the fourth phase region includes a triangular portion and a concave-shaped portion.

9. The vortex mask of claim 8, wherein the third phase region and the triangular portion of the fourth phase region form a rectangular region, and the rectangular region is positioned in a rectangular concave of the concave-shaped portion.

10. The vortex mask of claim 1, wherein the first phase region and the third phase region are positioned in a mirror image manner.

11. A method for preparing a vortex mask, comprising the steps of:
forming a first phase region with a predetermined thickness, including:
(a) forming a polymer layer having the predetermined thickness on a substrate;
(b) changing the molecular structure of the polymer layer in a predetermined region; and
(c) removing a portion of the polymer layer outside the predetermined region; and
repeating the steps (a), (b) and (c) to form a second phase region and a third phase region with different thicknesses.

12. The method for preparing a vortex mask of claim 11, wherein the step of forming a polymer layer having the predetermined thickness on the substrate includes performing a spin-coating process.

13. The method for preparing a vortex mask of claim 11, wherein the polymer layer includes hydrogen silsesquioxane, methylsilsesquioxane or hybrid organic siloxane polymer.

14. The method for preparing a vortex mask of claim 13, wherein the step of removing a portion of the polymer layer outside the predetermined region includes using an alkaline solution or an alcohol solution.

15. The method for preparing a vortex mask of claim 14, wherein the alkaline solution is selected from the group consisting of sodium hydroxide, potassium hydroxide, and tetramethylamomnium hydroxide.

16. The method for preparing a vortex mask of claim 14, wherein the alcohol solution includes an ethanol solution.

17. The method for preparing a vortex mask of claim 14, wherein the step of removing a portion of the polymer layer outside the predetermined region includes using a propyl acetate solution.

18. The method for preparing a vortex mask of claim 11, wherein the third phase region forms a point connection with the first phase region and the second phase region.

19. The method for preparing a vortex mask of claim 11, wherein the step of changing the molecular structure of the polymer layer in a predetermined region includes irradiating an electron beam on the predetermined region.

20. The method for preparing a vortex mask of claim 11, wherein the step of changing the molecular structure of the polymer layer in a predetermined region include providing energy to the predetermined region.

21. A method for preparing a circular pattern, comprising the steps of:
forming a photoresist layer on a substrate;
exposing the photoresist layer by using a vortex mask, including:
a substrate;
a first phase region positioned on the substrate;
a second phase region surrounding the first phase region; and
a third phase region positioned on the substrate and connecting
to the first phase region and the second phase region; and
developing the photoresist layer to form the circular pattern at a position corresponding to an intersection of the first phase region, the second phase region and the third phase region.

22. The method for preparing a circular pattern of claim 21, wherein the first phase region and the second phase region are configured to generate 90 degrees of phase difference for a penetrating exposing light.

23. The method for preparing a circular pattern of claim 21, wherein the first phase region and the third phase region are configured to generate 90 degrees of phase difference for a penetrating exposing light.

24. The method for preparing a circular pattern of claim 21, wherein the first phase region is triangular, and the second phase region includes a triangular portion and a concave-shaped portion.

25. The method for preparing a circular pattern of claim 24, wherein the first phase region and the triangular portion of the second phase region form a rectangular region, and the rectangular region is positioned in a rectangular concave of the concave-shaped portion.

26. The method for preparing a circular pattern of claim 21, wherein the first phase region and the third phase region are positioned in a mirror image manner.
